(19) United States
(12) Patent Application Publication
(10) Pub. No.: US 2025/0132163 A1
(43) Pub. Date: Apr. 24, 2025

(54) ENGINEERING EPI STACKS FOR EXTREME WAFER THINNING

(71) Applicant: Applied Materials, Inc., Santa Clara, CA (US)

(72) Inventors: Raghuveer Satya MAKALA, Santa Clara, CA (US); Ruiying HAO, Santa Clara, CA (US); Devika S. GRANT, Santa Clara, CA (US); Balasubramanian PRANATHARTHIHARAN, Santa Clara, CA (US)

(21) Appl. No.: 18/894,659

(22) Filed: Sep. 24, 2024

Related U.S. Application Data
(60) Provisional application No. 63/609,781, filed on Dec. 13, 2023.
(60) Provisional application No. 63/545,533, filed on Oct. 24, 2023.

(51) Int. Cl. H01L 21/308; H01L 21/02; H01L 21/033; H01L 23/00

(52) U.S. Cl. CPC H01L 21/3086; H01L 21/02381; H01L 21/02529; H01L 21/02532; H01L 21/0262; H01L 21/0332; H01L 21/0337; H01L 21/3081; H01L 24/29; H01L 24/32; H01L 24/83; H01L 2224/29186; H01L 2224/29686; H01L 2224/32225; H01L 2224/83193; H01L 2924/01006; H01L 2924/01032

(57) ABSTRACT

Embodiments of the present disclosure include a thinned device structure and method of forming a thinned device structure. Embodiments of the disclosure provided herein include the use of engineered epitaxial (Epi) layers that are formed on a base substrate. The engineered epitaxial layers include two or more epitaxial layers that each include materials that allow at least one of the two or more epitaxial layers to be selectively removed from the other layer(s). In some embodiments, one of the two or more formed epitaxial layers has etch selectivity (e.g., wet and/or dry etch selectivity) to materials disposed on either side of the formed layer.

### CROSS-REFERENCE TO RELATED APPLICATIONS

This application claims priority to U.S. Provisional Application Ser. No. 63/545,533 filed Oct. 24, 2023, and Ser. No. 63/609,781 filed Dec. 13, 2023, each of which is herein incorporated by reference in its entirety.

### BACKGROUND

### Field

Embodiments of the disclosure relate to the field of semiconductor manufacturing and, in particular, to systems and methods for forming thin substrates for use in device packages.

### Description of the Related Art

Wafer to wafer bonding enables heterogenous integration and opens up new ways to integrate logic and memory devices. In applications that involve access to a crystalline silicon (Si) surface from the device wafer's rear-side, almost all of the substrate (˜775 μm) needs to be removed by grinding, polishing and wet cleans. However, typical device manufacturers place stringent requirements on the total thickness remaining (100's of nm) and total thickness variation (˜10's of nm) after performing these thinning processes. Wafer grinding and CMP solutions that are used today cannot achieve precise control of the total thickness remaining and the total thickness variation.

The above is particularly important in the formation of advanced memory and logic devices, such as 4F2 DRAM device structures, where access to both sides of the formed vertical transistor (VT) portion of the structure is necessary. One costly option is to use SOI wafers where in the backside Si can be removed post grinding, which is then followed by an etch process, which stops on the SiO₂ layer, and is then followed by dilute hydrofluoric acid (dHF) etch of the SiO₂ layer to reveal the underlying silicon (Si) layer. However, SOI wafers are very expensive to form: >6×-10× compared to Si wafers and generally do not allow the formation of a high-quality epitaxial Si layer to be formed thereon (e.g., remaining Si layer).

Therefore, there is a need for a process of forming a thinned device structure that solves the problems described herein.

### SUMMARY

This summary is provided to introduce a selection of concepts that are further described below in the detailed description. However, many modifications are possible without materially departing from the teachings of this disclosure. Accordingly, such modifications are intended to be included within the scope of this disclosure as defined in the claims. This summary is not intended to identify key or essential features of the claimed subject matter, nor is it intended to be used as an aid in limiting the scope of the claimed subject matter.

Embodiments of the disclosure include a method of forming a semiconductor device, comprising bonding a component substrate assembly to a semiconductor device structure assembly that comprises: a first layer disposed over a first side of a base substrate; a second layer disposed over a surface of the first layer; a third layer disposed over a surface of the second layer; a semiconductor device structure, wherein the semiconductor device structure comprises a portion of the third layer; and a bonding layer disposed over the semiconductor device structure. The process of bonding of the component substrate assembly to the semiconductor device structure assembly comprises bonding a component substrate bonding layer formed on the component substrate assembly to the bonding layer formed over semiconductor device structure assembly. The method includes removing a portion of the base substrate disposed on a second side of the base substrate by use of first material removal process; removing the remaining portion of the base substrate by use of a second material removal process, wherein the second material removal process comprises an etching process that includes the use of an etchant chemistry that selectively removes the portions of the base substrate relative to the material of the first layer; removing the first layer by use of a third material removal process, wherein the third material removal process comprises an etching process that includes the use of an etchant chemistry that selectively removes the first layer relative to the material of the second layer; and removing the second layer by use of a fourth material removal process, wherein the fourth material removal process comprises an etching process that removes the second layer relative to the material of the third layer.

Embodiments of the disclosure may also include a method of forming a semiconductor device, comprising: forming a first layer over a first side of a base substrate; forming a second layer over a surface of the first layer; forming a third layer over a surface of the second layer, wherein the third layer is configured to form part of a semiconductor device. Then forming a semiconductor device structure, wherein the semiconductor device structure comprises a portion of the third layer. Forming a bonding layer over the semiconductor device structure; attaching a component substrate assembly to the bonding layer, wherein attaching the component substrate assembly to the bonding layer comprises bonding a component substrate bonding layer formed on the component substrate assembly to the bonding layer formed over semiconductor device structure. Then removing a portion of the base substrate disposed on a second side of the base substrate by use of first material removal process; removing the remaining portion of the base substrate by use of a second material removal process, wherein the second material removal process comprises an etching process that includes the use of an etchant chemistry that selectively removes the portions of the base substrate relative to the material of the first layer; removing the first layer by use of a third material removal process, wherein the third material removal process comprises an etching process that includes the use of an etchant chemistry that selectively removes the first layer relative to the material of the second layer; and removing the second layer by use of a fourth material removal process, wherein the fourth material removal process comprises an etching process that removes the second layer relative to the material of the third layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a flowchart illustrating a process of forming a thinned device structure, according to one or more embodiments described herein.

FIGS. 2A-2I include a cross-sectional views following the series of operations illustrated in FIG. 1 that are used to form of a thinned device structure, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure include a thinned device structure and method of forming a thinned device structure. Embodiments of the disclosure provided herein include the use of engineered epitaxial (Epi) layers that are formed on a base substrate. The engineered epitaxial layers include two or more epitaxial layers that each include materials that allow at least one of the two or more epitaxial layers to be selectively removed from the other layer(s). In some embodiments, one of the two or more formed epitaxial layers has a desirable etch selectivity (e.g., wet and/or dry etch selectivity) to materials disposed on either side of the formed epitaxial layer.

In one example, the engineered epitaxial layers include an Epi carbon doped silicon (C-doped) layer that is formed on a surface of a base substrate (e.g., crystalline Si substrate) and an Epi germanium doped silicon (e.g., Ge-doped Si) layer that is formed on the Epi carbon doped silicon layer. In this example, the carbon doped silicon (C-doped) layer acts as a dual etch stop layer, which allows the germanium doped silicon layer to be selectively removed from one side of the carbon doped silicon layer by a first etching process and an epitaxially formed silicon layer (Epi-Si) layer to be selectively processed from the opposing side of the carbon doped silicon layer during a different stage of the processing sequence.

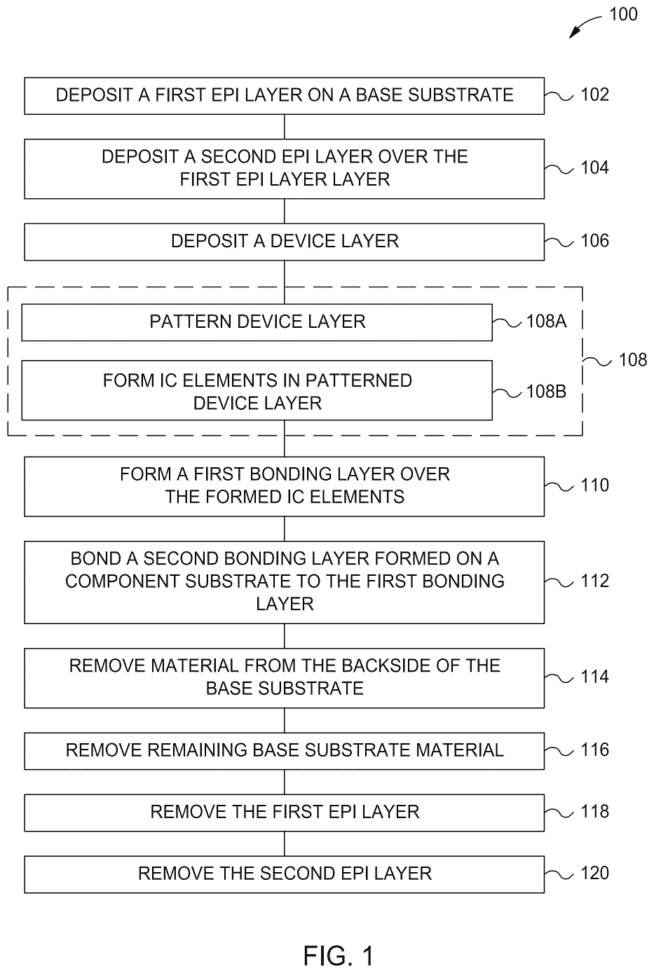

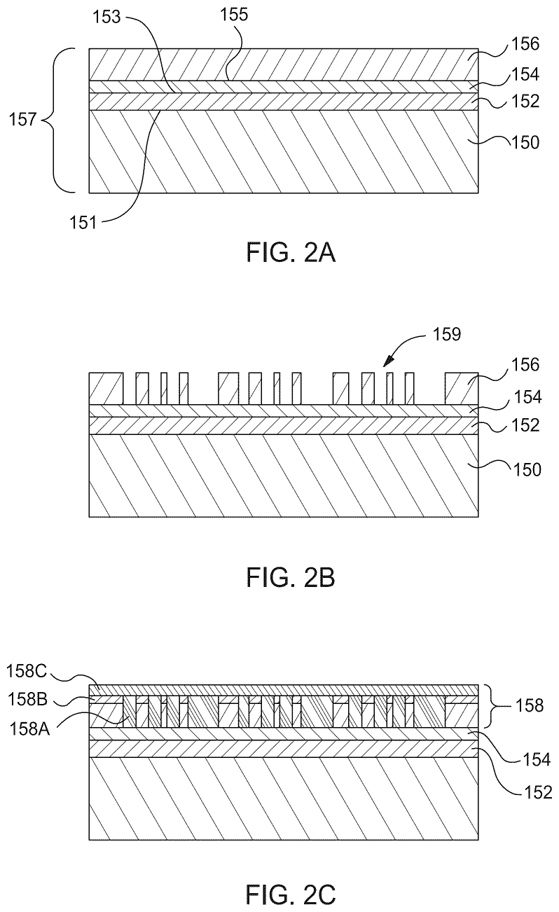

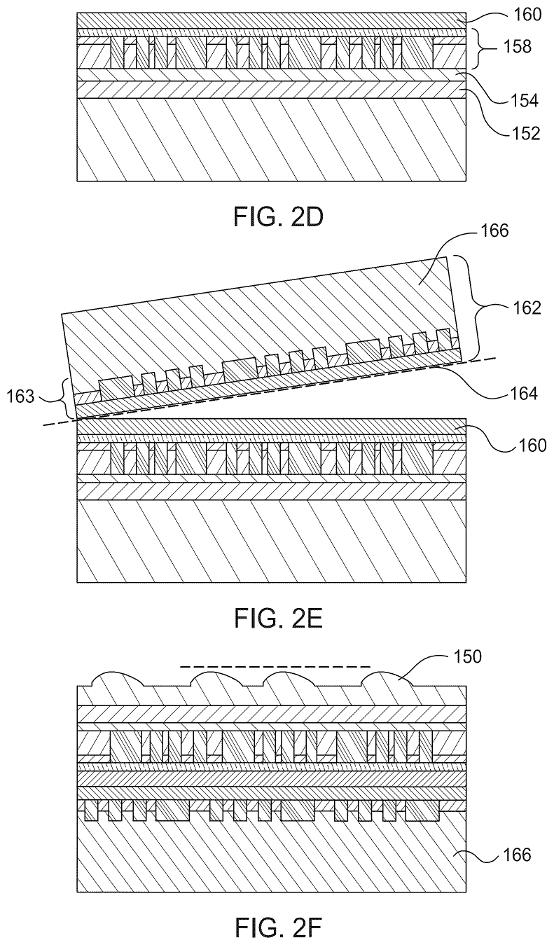

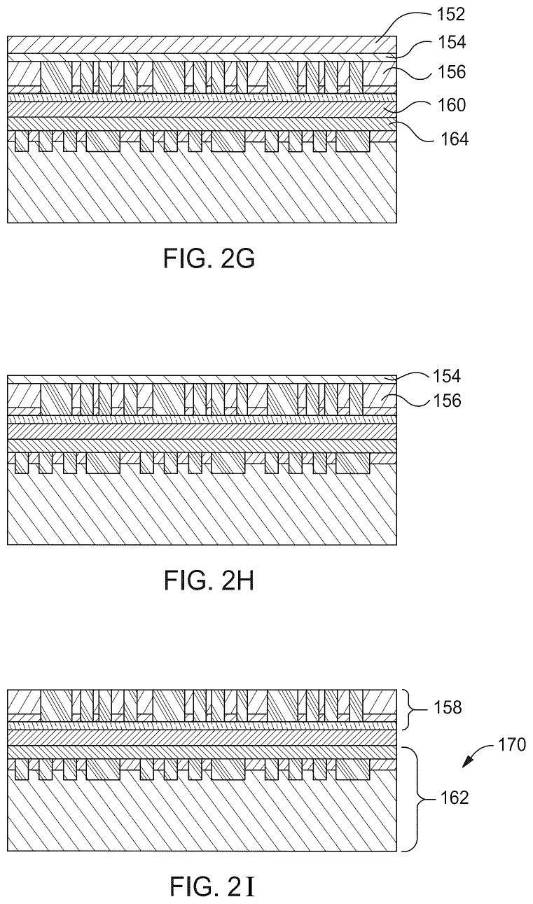

FIG. 1 is a flowchart illustrating a method 100 that is used to form a thinned device structure 170. FIGS. 2A-2I include cross-sectional views following the series of operations illustrated in FIG. 1 which are used to form of a thinned device structure 170. The thinned device structure 170 is believed to be useful in the formation both logic and memory devices, which can include, but are not limited to, the formation of dynamic random-access memory (DRAM) devices (e.g., 4F2 DRAM), 3D memory devices (e.g., 3D NAND), backside power delivery network (BSPDN) containing devices, and complementary field-effect transistor (CFET) containing devices. Semiconductor processing systems that contain processing chambers, such as wet and dry processing chambers, can be used to perform the processing steps described herein.

At operation 102, as illustrated in FIG. 2A, a first epitaxial layer 152 is formed on a surface of a base substrate 150. In one embodiment, the first epitaxial layer 152 includes an epitaxially grown germanium-doped silicon layer that is formed on a first surface 151 of the base substrate 150, which is a silicon (Si) substrate. In some embodiments, the base substrate 150 includes a 100 mm, 150 mm, 200 mm, 300 mm or even a 450 mm crystalline silicon (Si) substrate. In one example, the first epitaxial layer 152 is a germanium-doped silicon layer that includes between about 5% and 30% atomic percent (at. %) of germanium (Ge) in the epitaxially grown silicon layer that has a thickness between about 10-50 nm. In some embodiments, germanium (Ge) concentration in the first epitaxial layer 152 is uniform. In some embodiments, germanium (Ge) concentration varies vertically along the thickness of the first epitaxial layer 152 between the first surface 151 of the base substrate 150 and a first surface 153 of the first epitaxial layer 152 (i.e., an interface of the first epitaxial layer 152 and a second epitaxial layer 154 to be formed on the first surface 153). In one example, the first epitaxial layer 152 includes a portion with higher germanium (Ge) concentration near the first surface 151 of the base substrate 150 and a portion with lower germanium (Ge) concentration near the first surface 153 of the first epitaxial layer 152. In one example, the first epitaxial layer 152 includes portions with higher germanium (Ge) concentration near the first surface 151 of the base substrate 150 and near the first surface 153 of the first epitaxial layer 152, and a portion with lower germanium (Ge) concentration there between. In one example, the first epitaxial layer 152 includes portions with lower germanium (Ge) concentration near the first surface 151 of the base substrate 150 and near the first surface 153 of the first epitaxial layer 152, and a portion with higher germanium (Ge) concentration therebetween. In another example, germanium (Ge) concentration has a gradient with higher concentration near the first surface 151 of the base substrate 150 and lower concentration near the first surface 153 of the first epitaxial layer 152.

The first epitaxial layer 152 may additionally include other dopants, such as carbon (C). In one example, the first epitaxial layer 152 includes a SiGe layer that can be grown by a chemical vapor deposition (CVD) process at a temperature from 400° C. to 800° C.

At operation 104, as also illustrated in FIG. 2A, a second epitaxial layer 154 is formed on the first epitaxial layer 152. In one embodiment, the second epitaxial layer 154 includes an epitaxially grown carbon-doped silicon layer that is formed on the first surface 153 of the first epitaxial layer 152. In one example, the second epitaxial layer 154 is a carbon-doped silicon layer that includes between about 0.05% and 2% at. % of carbon (C) in the epitaxially grown silicon layer that has a thickness between about 10-60 nm. The second epitaxial layer 154 may additionally include other dopants, such as boron (B), arsenic (As), phosphorus (P) or germanium (Ge). In one example, the second epitaxial layer 154 can be grown by a chemical vapor deposition (CVD) process at temperature from 400° C. to 800° C.

At operation 106, as also illustrated in FIG. 2A, a third epitaxial layer 156 is formed on the second epitaxial layer 154 to form a stacked epitaxial layer structure 157 that includes first epitaxial layer 152, the second epitaxial layer 154, the third epitaxial layer 156 and the base substrate 150. In one embodiment, the third epitaxial layer 156 is a device layer that is subsequently used to form portions of one or more integrated circuit (IC) devices, such as portions of or complete semiconductor devices (e.g., 4F2 DRAM device structure). In some embodiments, the third epitaxial layer 156 includes an epitaxially grown silicon layer that is formed on a first surface 155 of the second epitaxial layer 154. In some embodiments, the third epitaxial layer 156 is an undoped Epi silicon layer that has a thickness between about 100 and about 300 nm. In one example, the third epitaxial layer 156 can be grown by a chemical vapor deposition (CVD) process at temperature from 400° C. to 800° C.

At operation 108, a plurality of semiconductor processing steps are performed on the third epitaxial layer 156 of the stacked epitaxial layer structure 157 to form a device structure 158 that includes portions of or complete semiconductor devices. The semiconductor processing steps can include lithography and patterning steps, etching steps, deposition steps, polishing steps, thermal processing steps or other useful steps that are needed to form the semiconductor devices.

In some embodiments, operation 108 includes a first operation 108A that includes a series of process steps that is used to form patterned features 159 within the third epitaxial layer 156, as shown in FIG. 2B. During the process of forming the patterned features 159, which includes lithography and other common patterning process steps, an etching process is used to form the patterned features 159 within the third epitaxial layer 156. The etching process will generally include the use of one or more etchants that will remove patterned portions of the third epitaxial layer 156 and stop etching when the etched features reach the second epitaxial layer 154. In other words, the second epitaxial layer 154 will act as an etch stop during the formation of the patterned features in the third epitaxial layer 156. In one example, the second epitaxial layer 154 is a carbon-doped Epi Si layer and the etchant used to form the features in an undoped Si containing third epitaxial layer 156 includes wet or dry etching chemistries that are configured to selectively etch the undoped Si layer versus the carbon-doped Epi Si layer. The use of a carbon-doped Epi silicon layer in a stacked epitaxial layer structure 157 that includes a first epitaxial layer 152 that comprises silicon and germanium (SiGe), can provide multiple benefits as it preforms two main roles during the processing sequence, which include: (1) acting as etch stop layer, and (2) acting as a barrier layer to block germanium diffusion into the third epitaxial layer 156 (e.g., the Si epitaxial layer) due to the presence of the first epitaxial layer 152, which is positioned on an opposing side of the second epitaxial layer 154.

Operation 108 will typically further include a second operation 108B (FIG. 2C) that includes the additional formation process steps used to form the device structure 158 that can include portions of or complete semiconductor devices. The additional formation process steps can include the deposition processes (e.g., PVD, CVD, and/or ALD processes), thermal processing process, chemical mechanical polishing (CMP) processes, and other useful processing steps used to form a semiconductor device, which are all performed on the base substrate 150 and formed and patterned layers formed thereon. The device structure 158 can include multiple device layers, such as one or more metal or isolation layers 158A, patterning layers 158B, and an isolation layer 158C.

At operation 110, a bonding layer 160 is formed over the device structure 158. As shown in FIG. 2D, the bonding layer 160 is formed on the isolation layer 158C. In some embodiments, where fusion type bonding is used, the bonding layer 160 includes one or more dielectric layers. In some other embodiments, where a hybrid bonding process is used, the bonding layer 160 will consist of one or more layers of a dielectric and one or more metal (e.g., Cu, Mo, Ti, etc.) layers that are configured to form the conductive traces and bond pads. In general, the bonding layer 160 will have a good bond strength to an adjacently positioned bond layer and also be amenable to CMP for planarization prior to bonding. In some embodiments, the bonding layer 160 can include materials selected from the group of SiO₂, SiCN, SiN, SiOCN, and AlOx. However, other useful bonding layer materials may be used. In some embodiments, the bonding layer 160 can be formed by use of chemical vapor deposition (CVD), physical vapor deposition (PVD), evaporation process (e.g., MBE), plasma-enhanced chemical vapor deposition (PECVD), spin-on process or other useful deposition process.

At operation 112, as shown in FIG. 2E, a component substrate assembly 162 is bonded to the device structure 158 side of the structures formed on the base substrate 150. During operation 112, a component substrate bonding layer 164, which is formed on a surface of the component substrate assembly 162, is bonded to the bonding layer 160 formed on the device structure 158. In some embodiments, the component substrate bonding layer 164 includes the same material as the material used to form the bonding layer 160. In some embodiments, where fusion type bonding is used, the component substrate bonding layer 164 includes one or more dielectric layers. As noted above, in some other embodiments, where a hybrid bonding process is used, the component substrate bonding layer 164 will also consist of one or more layers of a dielectric and one or more metal layers (e.g., Cu, Mo, Ti, etc.) that are configured to form the conductive traces and bond pads that are configured to be bonded to the conductive traces and bond pads formed in the bonding layer 160. In one example, the bonding layer 160 and the component substrate bonding layer 164 both include materials selected from the group of SiO₂, SiCN, SiN, SiOCN, and AlOx, and have a thickness between 1 μm and 2 μm. However, other useful bonding layer materials may be used. In some embodiments, the component substrate assembly 162 includes portions of one or more integrated circuit (IC) devices, interconnects or other circuit elements formed in a device region 163 that is formed on or within a component substrate 166. The one or more integrated circuit (IC) devices, interconnects or other circuit elements formed in a device region 163 can include, for example, complementary metal-oxide-semiconductor (CMOS) devices useful for controlling DRAM or logic devices, or even includes portions of the DRAM device such as bit line portion or capacitor portion. The component substrate 166 can include a semiconductor substrate, such as a silicon containing substrate. In some embodiments, the component substrate 166 includes a 100 mm, 150 mm, 200 mm, 300 mm or even a 450 mm crystalline silicon (Si) substrate, which generally matches the size of the base substrate 150. In some other embodiments, the component substrate assembly 162 is die, which can be used in a device package, that is bonded to a region of the surface of the bonding layer 160 formed over the larger base substrate 150.

In some embodiments, the component substrate bonding layer 164 and the bonding layer 160 each include embedded metal interconnect layers that can be used to form a hybrid bonding connection between the devices formed in the device structure 158 and the devices formed on or within the device region 163 of the component substrate assembly 162. In this case, the process of bonding the substrates together will require an alignment process that allows the connections formed in the component substrate bonding layer 164 and the bonding layer 160 to make the desired interconnections during the bonding process. In other configurations, the component substrate bonding layer 164 and the bonding layer 160 are simply used to form a fusion bond between the component substrate assembly 162 and the device structure 158 and layers formed on the base substrate 150.

At operation 114, as shown in FIG. 2F, at least a portion of the backside surface of the base substrate 150 is removed by use of a grinding process, such as a chemical mechanical polishing (CMP) process. Operation 114 can include a coarse grinding process that is then followed with a CMP process. In one non-limiting example, the grinding process is performed on the base substrate 150 until between about 1 micron (μm) and about 12 μms of the base substrate material remains (e.g., Si material).

In some embodiments of operation 114, an edge trimming process is performed, which is configured to remove a portion of the base substrate 150, the first epitaxial layer 152, second epitaxial layer 154, third epitaxial layer 156 and the bonding layer 160 found in an edge region of the bonded structure, while leaving at least a portion of the component substrate assembly 162 at the edge region. In some embodiments, the edge region is between about 1 mm and 5 mm at the peripheral edge of the base substrate 150. The edge trimming process can be performed by use of a laser ablation, mechanical scribing, polishing or grinding process.

At operation 116, as shown in FIG. 2G, an etching process is performed on the backside surface of the base substrate 150 to selectively remove the remaining portions the base substrate 150 leftover after performing operation 114. It is generally desirable for various parts of the component substrate assembly 162 and device structures 158 to be isolated from the processes used to selectively remove the remaining portions the base substrate 150. In some cases, the various parts of the component substrate assembly 162 and device structures 158 are isolated from processes performed in operation 116 by use of a physical barrier (e.g., deposited molding layer, tape layer or other similar structure). The etching process performed in operation 116 will include the use of an etchant that will remove base substrate material and stop etching when the first epitaxial layer 152 is exposed during the etching process. In other words, the first epitaxial layer 152 will act as an etch stop during the removal of the base substrate material. In one example, the first epitaxial layer 152 is a germanium-doped Epi Si layer and the etchant used to remove the remaining portions of the base substrate material includes wet or dry etching chemistries that are configured to selectively etch the undoped Si material of the base substrate 150 versus the germanium-doped Epi Si layer. In one example of a wet chemistry process, the chemistry can include tetramethylammonium hydroxide (TMAH), tetraethylammonium hydroxide (TEAH), and ammonia hydroxide (NH₄OH), or combinations thereof.

At operation 118, as shown in FIG. 2H, an etching process is performed to selectively remove the first epitaxial layer 152. The etching process will include the use of an etchant that will remove the first epitaxial layer 152 and stop etching downward when the second epitaxial layer 154 is exposed during the etching process. In other words, the second epitaxial layer 154 will act as an etch stop during the removal of the first epitaxial layer 152. In one example, the second epitaxial layer 154 is a carbon-doped Epi Si layer and the etchant used to remove the first epitaxial layer 152 includes wet or dry etching chemistries that are configured to selectively etch the germanium-doped Epi Si layer material versus the carbon-doped Epi Si layer. In some embodiments, operation 118 can include exposing the first epitaxial layer 152 to a wet process performed in a liquid processing chamber and/or a dry process that can include exposing the first epitaxial layer 152 to radicals and/or a plasma formed in a plasma processing chamber. In one example of a wet chemistry process the chemistry can include a HNO₃/HF/CH₃COOH mixture. In one example of a dry process the process gas can include at least one of NF₃, F2 and ClF₃.

At operation 120, as shown in FIG. 2I, an etching process is performed to selectively remove the second epitaxial layer 154. The etching process is designed to remove the second epitaxial layer 154 and stop or minimally etch the layers used to form the device structure 158. Due to the typical minimal etch rate difference between the commonly used material used to form the second epitaxial layer 154 and the layers in the device structure 158, the selectivity of the etching process performed during operation 120 is predominantly controlled by controlling the timing of the completion of the operation 120. In other words, the wet or dry etching chemistries used to remove the second epitaxial layer 154, while selected so that they tend to selectively etch the second epitaxial layer 154 versus the layers of the device structure 158 that are exposed during and after the etching process, the second epitaxial layer 154 thickness and etching chemistry etch rate at the etching process conditions needs to be controlled to allow the second epitaxial layer 154 to be substantially removed while not significantly etching the material(s) within the device structure 158. In some embodiments, operation 120 can include exposing the second epitaxial layer 154 to a wet process performed in a liquid processing chamber and/or a dry process that can include exposing the second epitaxial layer 154 to radicals and/or a plasma formed in a plasma processing chamber.

However, in some other embodiments of operation 120, the selectivity of the etching process performed during operation 120 can be controlled by use of a metrology-based endpoint detection process that is able to detect the completion of the selective removal of the second epitaxial layer 154 during operation 120. In one example, optical or etching byproduct analysis techniques (e.g., RGA) can be used to detect the endpoint of one or more of the processes performed during operation 120.

In one example of operation 120, the second epitaxial layer 154 is a carbon-doped Epi Si layer and the etchant used to remove the second epitaxial layer 154 includes wet or dry etching chemistries that are configured to selectively etch the carbon-doped Epi Si layer material versus an undoped Epi Si layer. In one example of a wet or dry process can include HF, NH₄OH and H₂O₂, and combinations thereof.

As noted above, method 100 can be used to form a thinned device structure 170 (FIG. 2I) that essentially includes the remaining device structure 158 and the device region 163 of the component substrate assembly 162. In some embodiments, it is desirable to also remove at least portion of the backside of the component substrate 166 (i.e., thin the component substrate 166).

In some embodiments, the method 100 may be further extended to include the formation of DRAM capacitor structures over the exposed surface of the device structure 158. In some embodiments, the exposed surfaces of the device structure 158 are then further processed, such as performing one or more of the following semiconductor processing steps. The semiconductor processing steps can include, but are not limited to ion-implantation steps, metal and/or dielectric material deposition steps, lithography and patterning steps, etching steps, polishing steps, thermal processing steps or other useful steps that are needed to form one or more semiconductor devices.

While the foregoing is directed to embodiments of the present disclosure, other and further embodiments of the disclosure may be devised without departing from the basic scope thereof, and the scope thereof is determined by the claims that follow.

What is claimed is:

1. A method of forming a semiconductor device, comprising:
depositing a first epitaxial layer disposed over a first side of a base substrate;
depositing a second epitaxial layer disposed over a surface of the first epitaxial layer;
depositing a third epitaxial layer disposed over a surface of the second epitaxial layer;
forming a first semiconductor device structure, wherein the forming comprises etching patterned portions of the third epitaxial layer while using the second epitaxial layer as a stop layer for the etching; and
from a second side of the base substrate, removing the base substrate by use of one or more first material removal processes while using the first epitaxial layer as a stop layer for the one or more first material removal processes; and
removing the first epitaxial layer and the second epitaxial layer to expose the third epitaxial layer by use of one or more second material removal processes.

2. The method of claim 1, wherein the one or more second material removal processes comprise an etching process that includes the use of an etchant chemistry that selectively removes the first epitaxial layer and the second epitaxial layer relative to the third epitaxial layer.

3. The method of claim 1, further comprising:
prior to the removing of the base substrate, bonding a bonding layer to the first semiconductor device structure and a component substrate assembly to the bonding layer.

4. The method of claim 3, wherein:
the first epitaxial layer, the second epitaxial layer, and the third epitaxial layer each comprise an epitaxial (Epi) layer,
the first epitaxial layer further comprises silicon (Si) and germanium (Ge),
the second epitaxial layer further comprises silicon (Si) and carbon (C),
the third epitaxial layer further comprises undoped silicon (Si),
the base substrate comprises silicon (Si), and
the bonding layer and the component substrate bonding layer each comprise a material selected from the group of SiO₂, SiCN, SiN, SiOCN, and AlOx, and have a thickness between 1 μm and 2 μm.

5. The method of claim 4, wherein:
the first epitaxial layer further comprises carbon (C); and
the second epitaxial layer further comprises germanium (Ge).

6. The method of claim 4, wherein:
the first epitaxial layer comprises between about 5 at. % and about 30 at. % of germanium in silicon and has a thickness between 10 and 50 nm,
the second epitaxial layer comprises between about 0.05 at. % and about 2 at. % of carbon in silicon and has a thickness between 10 and 60 nm, and
the third epitaxial layer has a thickness between 100 and 300 nm.

7. The method of claim 6, wherein concentration of germanium is uniform in the first epitaxial layer.

8. The method of claim 6, wherein the first epitaxial layer includes a portion with higher germanium (Ge) concentration near a first surface of the base substrate and a portion with lower germanium (Ge) concentration near the first surface of the first epitaxial layer.

9. The method of claim 6, wherein the first epitaxial layer includes portions with higher germanium (Ge) concentration near a first surface of the base substrate and near the first surface of the first epitaxial layer, and a portion with lower germanium (Ge) concentration there between.

10. The method of claim 6, wherein the first epitaxial layer includes portions with lower germanium (Ge) concentration near a first surface of the base substrate and near the first surface of the first epitaxial layer, and a portion with higher germanium (Ge) concentration therebetween.

11. The method of claim 6, wherein germanium (Ge) concentration of the first epitaxial layer has a gradient with higher concentration near a first surface of the base substrate and lower concentration near the first surface of the first epitaxial layer.

12. The method of claim 1, wherein:
the etching of the patterned portions of the third epitaxial layer uses an etchant chemistry that selectively removes the portions of the third epitaxial layer relative to the material of the second epitaxial layer, and
the one or more second material removal processes comprise:
removing the first epitaxial layer by use of an etching process that includes the use of an etchant chemistry that selectively removes the first epitaxial layer relative to the material of the second epitaxial layer; and
removing the second epitaxial layer by use of an etching process that removes the second epitaxial layer relative to the material of the third epitaxial layer.

13. A method of forming a semiconductor device, comprising:
forming a first epitaxial layer over a first side of a base substrate;
forming a second epitaxial layer over a surface of the first epitaxial layer;
forming a third epitaxial layer over a surface of the second epitaxial layer, wherein the third epitaxial layer is configured to form part of a semiconductor device;
forming a semiconductor device structure, wherein the semiconductor device structure comprises a portion of the third epitaxial layer;
forming a bonding layer over the semiconductor device structure;
attaching a component substrate assembly to the bonding layer, wherein attaching the component substrate assembly to the bonding layer comprises bonding a component substrate bonding layer formed on the component substrate assembly to the bonding layer formed over semiconductor device structure;
removing a portion of the base substrate disposed on a second side of the base substrate by use of first material removal process;
removing the remaining portion of the base substrate by use of a second material removal process, wherein the second material removal process comprises an etching process that includes the use of an etchant chemistry that selectively removes the portions of the base substrate relative to the material of the first epitaxial layer;
removing the first epitaxial layer by use of a third material removal process, wherein the third material removal process comprises an etching process that includes the use of an etchant chemistry that selectively removes the first epitaxial layer relative to the material of the second epitaxial layer; and
removing the second epitaxial layer by use of a fourth material removal process, wherein the fourth material removal process comprises an etching process that removes the second epitaxial layer relative to the material of the third epitaxial layer.

14. The method of claim 13, wherein:
the forming the semiconductor device further comprises etching a portion of the third epitaxial layer to expose at least a portion of the second epitaxial layer, and the etching process uses an etchant chemistry that selectively removes the portions of the third epitaxial layer relative to the material of the second epitaxial layer,
the first epitaxial layer, the second epitaxial layer, and the third epitaxial layer each comprise an epitaxial (Epi) layer,
the first epitaxial layer further comprises silicon (Si) and germanium (Ge),
the second epitaxial layer further comprises silicon (Si) and carbon (C),
the third epitaxial layer further comprises undoped silicon (Si),
the base substrate comprises silicon (Si), and
the bonding layer and the component substrate bonding layer each comprise a material selected from the group of SiO₂, SiCN, SiN, SiOCN, and AlOx, and have a thickness between 1 μm and 2 μm.

15. The method of claim 13, wherein:
the first epitaxial layer further comprises carbon (C); and
the second epitaxial layer further comprises germanium (Ge).

16. The method of claim 13, wherein:
the first epitaxial layer comprises between about 5 at. % and about 30 at. % of germanium in silicon and has a thickness between 20 and 50 nm,
the second epitaxial layer comprises between about 0.1 at. % and about 2 at. % of carbon in silicon and has a thickness between 10 and 60 nm, and
the third epitaxial layer has a thickness between 100 and 300 nm.

17. The method of claim 16, wherein concentration of germanium is uniform in the first epitaxial layer.

18. The method of claim 16, wherein concentration of germanium varies along a thickness of the first epitaxial layer.

19. A thinned device structure, comprising:
a semiconductor device structure comprising:
a first epitaxial layer having first side, a second side opposite to the first side, and a thickness of between 100 and 300 nm, wherein the first side comprises an exposed surface;
a first bonding layer disposed over the semiconductor device structure and the second side of the first epitaxial layer; and
a component substrate assembly bonded to the first bonding layer, wherein the first bonding layer formed over semiconductor device structure is bonded to a second bonding layer, and the component substrate assembly comprises portions of one or more integrated circuit (IC) devices that are formed on or within a component substrate of the component substrate assembly.

20. The thinned device structure of the claim 19, wherein:
the first bonding layer comprises a fusion bonding layer; and
the second bonding layer comprises a fusion bonding layer.

21. The thinned device structure of the claim 19, wherein:
the first bonding layer comprises one or more metal interconnect layers;
the second bonding layer comprises one or more metal interconnect layers; and
the one or more metal interconnect layers of the first bonding layer and the one or more metal interconnect layers of the second bonding layer are in electrical communication.

22. The thinned device structure of claim 19, wherein:
the first bonding layer and the second bonding layer comprise a material selected from a group comprising at least one of SiO₂, SiCN, SiN, SiOCN, and AlOx.
